(19) United States
(12) Patent Application Publication
(10) Pub. No.: US 2008/0040056 A1
(43) Pub. Date: Feb. 14, 2008

(54) Battery recharging and replacement system

(75) Inventor: Minh Lee, Kensington (AU)

Correspondence Address: DANIEL B. SCHEIN, PH.D., ESQ., INC., P. O. BOX 68128, Virginia Beach, VA, 23471, US

(73) Assignee: Ventrassist PTY LTD. & The University of New South Wales

(21) Appl. No.: 11/890,393

(22) Filed: Aug. 6, 2007

(30) Foreign Application Priority Data
Aug. 11, 2006 (AU) 2006904376

(51) Int. Cl. G01R 31/36; G06F 19/00; H02J 7/00

(52) U.S. Cl. 702/63; 320/134

(57) ABSTRACT

A battery replacement system that is capable of detecting and measuring the remaining life in at least two batteries. When the system detects that the level of battery performance falls below a first predetermined range relative to overall battery life, the system defines a cluster of batteries and replaces the cluster of batteries. The cluster of batteries is defined by at least first and second batteries being proximal to each other in terms of battery life and within a predetermined second range in respect to each other.

### TECHNICAL FIELD

The present invention relates to a battery recharging and replacement system for use with a battery-powered device. The present invention is described with reference to a battery-powered implantable medical device.

### BACKGROUND

Most modern implantable medical devices are powered by rechargeable or replaceable batteries. Currently available rechargeable batteries have a limited life span in terms of how many times the batteries may be recharged before they fail. Additionally, rechargeable batteries have a finite shelf life prior to them deteriorating and failing. Also, it should be noted that the deterioration of a rechargeable battery towards the end of its life is not steady, but rather it is exponential.

Whilst in many other uses, such as music/audio players, electronic cameras and mobile phones, the deterioration and failure of rechargeable batteries whilst they are being used is not of critical importance. However, in implantable medical devices, such as a Left Ventricle Assist Device of the type described within U.S. Pat. No. 6,227,797 Watterson et al, the failure of batteries whilst they are powering the device may be life threatening, as it requires a continuous active power source.

In order to avoid the failure of a rechargeable battery, it is known to employ battery replacement systems to replace the rechargeable batteries that are typically used in sets or banks to power the Left Ventricle Assist Device (hereinafter referred to as “LVAS”).

Initially, battery replacement involves replacing banks of batteries being used with the LVAS on a periodic basis, well before the batteries begin to fail. As the rechargeable batteries used are of a type similar to those used for laptops and other portable personal computers, this replacement is quite costly. In order to better maximise the use of rechargeable batteries, battery systems have been employed where batteries are monitored and replaced when their retained charge begins to fail.

The operation of one such battery replacement system is shown in the graph of FIG. 2. The FIG. 2 graph shows three consecutive times 31, 32 and 33 and demonstrates several batteries aging. Each time 31, 32 and 33 depicts the progressive aging of two clusters of batteries. One of the clusters of batteries includes: a first 34, second 35 and third 36 batteries. As shown by the graph depicted in FIG. 2, as the cluster of batteries ages the first battery 34 enters a predefined replacement window 27.

Generally, once the first battery 34 enters the replacement window 27 as shown at time 32, the first battery 34 is replaced or ordered. The second and third batteries 35 and 66 are replaced at a later time interval shown at time 33. Thereby, the cluster of batteries in FIG. 2 is replaced through the use of multiple orders. This multiple ordering of batteries has the disadvantage of being complex, prone to error and expensive to maintain.

The present invention aims to at least partially overcome some of the disadvantages associated with prior art battery replacement systems.

### SUMMARY OF INVENTION

According to a first aspect the present invention consists in a battery recharging and replacement system for use with a battery-powered device, said system comprising: at least three rechargeable batteries each with a unique identifier;

a charger for charging said batteries;

a measurement means for measuring the remaining useful life of each of said batteries; and a monitor means for identifying that any one or more of said batteries are at or near the end of their usable life; and

wherein during use and charging of said batteries, said measurement means maintains a record of the remaining useful life of each said batteries, and when a first of said batteries enters a first predetermined range of overall cumulative discharge, said monitor means identifies that battery for imminent replacement, and then determines whether at least a second battery is within a second predetermined range centred on the first battery, if the first battery is within the first predetermined range and at least a second battery is within the second predetermined range, said monitor means identifies both batteries for replacement.

Preferably the remaining useful life is the inverse of cumulative discharge.

Preferably if the first of said batteries reaches the lower limit of remaining charge capacity prior to the second of said batteries reaches the upper limit of remaining charge capacity, then said monitor means will identify both batteries for replacement if said second battery is in a predetermined tolerance range near the upper limit of remaining charge capacity.

Preferably said monitor means is connected to a remotely located computer for the ordering and dispatch of batteries, said monitor means providing data to said computer when batteries are identified for replacement.

Preferably when said monitor means identifies said batteries for replacement said batteries are prevented from being recharged by said recharger.

Preferably said measurement means for measuring the cumulative discharge of each of said batteries, is a device interconnected to or integral with said recharger.

Preferably said measurement means for measuring the cumulative discharge of each of said batteries is a plurality of measurement devices, each of said measurement devices is disposed on and associated with a respective one of said batteries.

Preferably said measurement means for measuring the cumulative discharge of each of said batteries, is a measurement apparatus interconnected to or integral with said recharger and a plurality of measurement devices, each of said measurement devices disposed on and associated with a respective one of said batteries.

Preferably said measurement apparatus is adapted to maintain and record a separate record of cumulative discharge for a particular battery to that maintained and recorded by the measurement device associated with that particular battery.

Preferably said separate record of cumulative discharge maintained by said measurement apparatus may be compared with respect to that maintained and recorded by the measurement device associated with the respective battery.

According to a second aspect the present invention consists in a battery replacement system, wherein said system detects and measures remaining battery life in at least two batteries, and when said system detects that the level of battery performance falls below a first predetermined range relative to overall battery life, said system defines a cluster of batteries and replaces the cluster of batteries, wherein said cluster of batteries is defined by at least first and second batteries being proximal to each other in terms of battery life and within a predetermined second range in respect to each other.

### BRIEF DESCRIPTION OF DRAWINGS

FIG. 1 depicts a schematic view of a prior art implanted medical device powered by a rechargeable battery.

FIG. 2 depicts a graph of a prior art battery replacement system that can be used with the implanted medical device of FIG. 1.

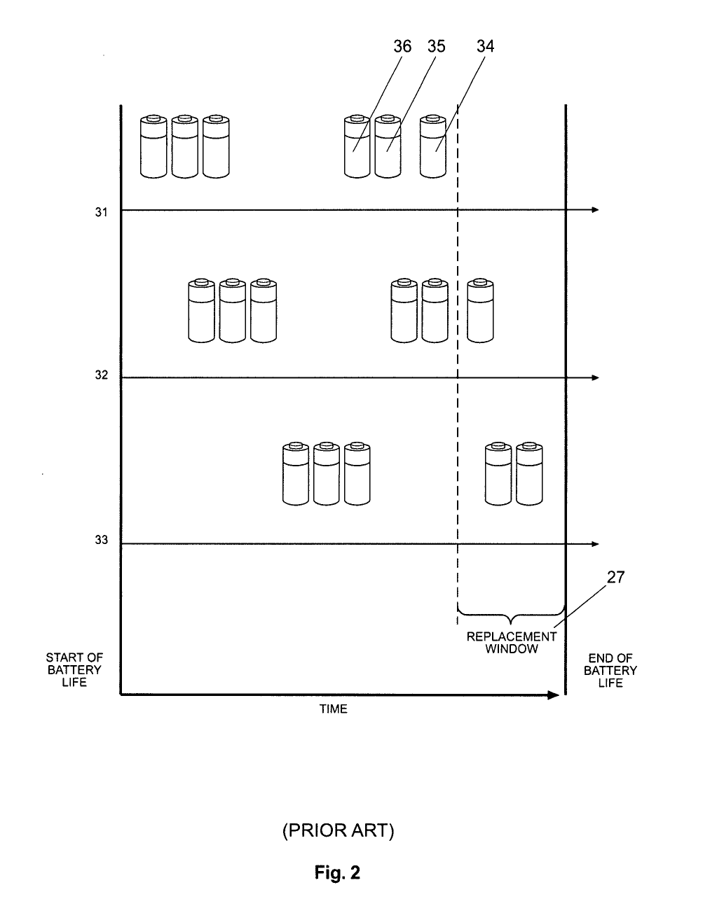

FIG. 3 depicts a battery recharging and replacement system according to a first embodiment of the present invention.

FIG. 4 depicts a graph depicting the operation of the battery recharging and replacement system of FIG. 3.

FIG. 5 depicts a flow chart of a battery order and supply system including the system shown in FIG. 3.

### DESCRIPTION OF CARRYING OUT INVENTION

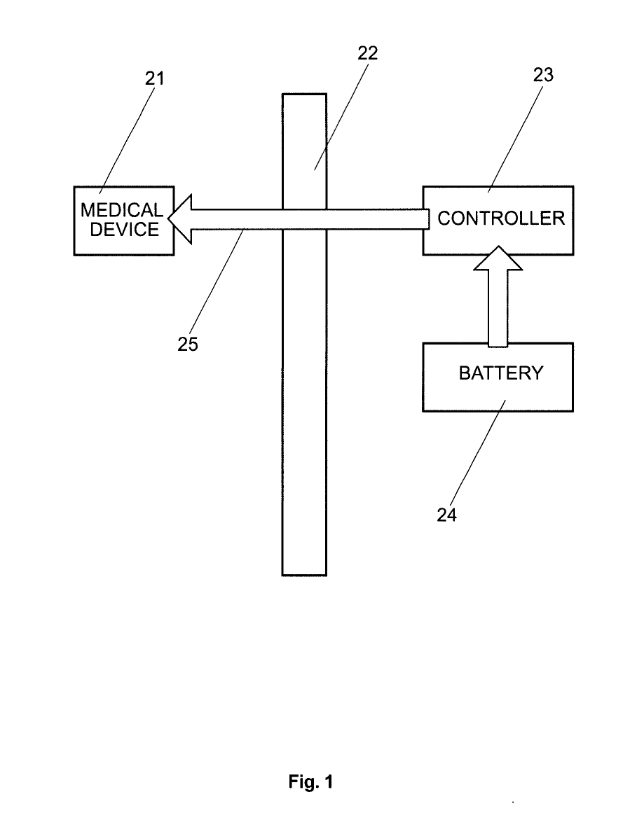

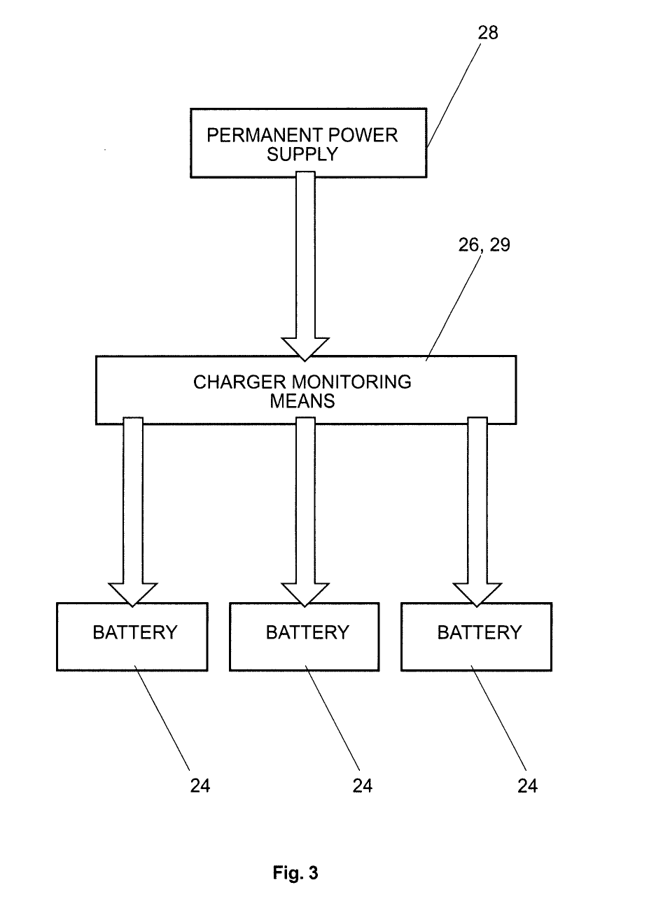

A first embodiment of a battery recharging and replacement system 1 is shown and described with reference to FIGS. 3 to 5. The battery recharging and replacement system 1 may be used with a prior art battery powered implanted medical device 21 of the type shown in FIG. 1. The medical device 1 is preferably powered and controlled via a percutaneous lead 25 connected to a controller 23 and battery 24 through the skin layer 22 of a patient. Whilst FIG. 1 depicts a single battery 24, it should be understood that controller 23 and/or medical device I may be powered by a plurality of batteries, sequentially or simultaneously. Preferably, battery 24 is a rechargeable battery, including but not limited to, nickel metal hydride and lithium ion batteries.

Battery recharging and replacement system 1 comprises a charger 26 for recharging a plurality of batteries 24. Charger 26 is powered from a permanent power supply 28, such as a mains outlet. A monitor means 29 for identifying the remaining useful life of batteries 24 is integrally housed within the housing of charger 26.

Each battery 24 has a unique identifier and an “electronic chip” for measurement of its “cumulative discharge”.

In use, every time a battery 24 is operably placed in charger 26 for recharging the monitor means 29 is able to read and records the “cumulative discharge” of that battery 24. The purpose of the monitor means 29 is to monitor the batteries such that they may “grouped” or “clustered” for replacement.

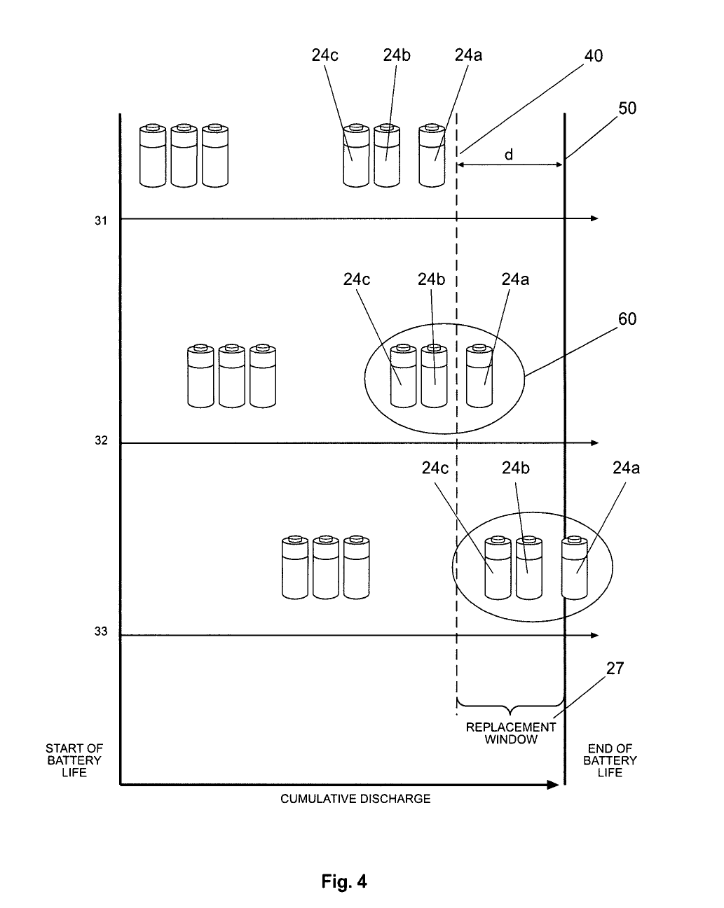

The monitor means 29 continuously monitors and records the cumulative discharge of each battery as it is discharged. The monitor means 29 is programmed to identify when a battery enters a first predetermined range of cumulative discharges, represented in FIG. 4 as “d”, between lines 40 and 50.

In FIG. 4 at time 31, three aging batteries are represented by 24a, 24b and 24c. As can be seen at time 32 of FIG. 4, when battery 24a has entered the first predetermined range of cumulative discharge, the monitor means 29 identifies this battery for imminent replacement. The monitor means 29 then also determined if any other batteries are within a second predetermined range of cumulative discharge centred on battery 24a within the first predetermined range. At time 32, this second predetermined range of cumulative discharge is represented by oval 60, and includes within it, all three batteries 24a, 24b and 24c. The monitor means 29 of system 1 has detected batteries 24a, 24b and 24c to form part of a cluster, and when all three batteries have entered the first predetermined range, the monitor means 29 will identify all three batteries for replacement, as is the case for time 33.

The first predetermined range of cumulative discharge may vary from system to system. However, in this embodiment the first predetermined range of cumulative discharge may for instance be between 87% and 95% inclusive of the cumulative discharge life. This would mean the upper limit of remaining charge capacity is 13% (line 40) and the lower limit of remaining charge capacity is 5% (line 50).

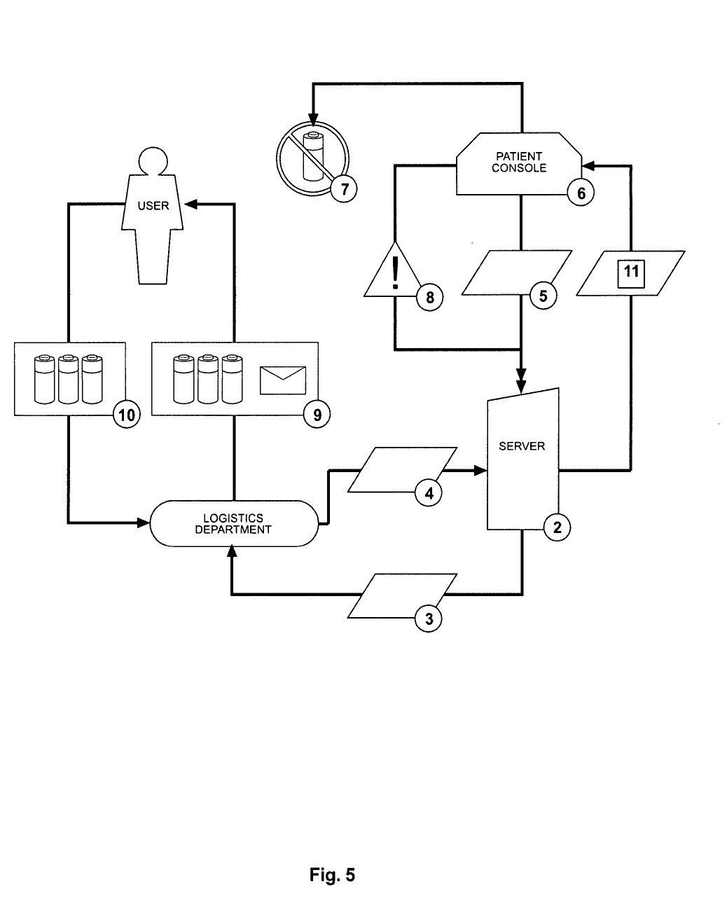

The system 1 preferably forms part of a larger system as shown in FIG. 5 as a flow chart. In FIG. 5, the patient console 6 stores and controls the data from system 1. The patient console 6 may preferably include charger 26 and may store data regarding battery identification as well as predicted end of life data for each battery.

When system 1 has determined that a “cluster” or group of batteries needs to be replaced, the patient console 6 sends data 5 to an external server 2.

The server 2 may then issue an electronic request to the logistics department of a battery supply company to order more batteries for the patient. The logistics department processes the order for new batteries and sends a first package 9 of new batteries to the patient. Upon receipt of the first package 9, the patient or user sends a second package 10, containing the replaced batteries 24a to 24c to the logistics department.

The logistics department sends data 4 to server indicating that batteries 24a to 24c have been replaced and also supplies the server with the serial number (or other unique identifiers) of the new batteries. The server 2 then relays data 4 to the patient console 6 by sending data 11.

If the patient console 6 of system 1 detects an error or defect in the new batteries, an error message 8 is sent to server 2 which can be detected by the user, patient and/or logistics department. When an error is detected, new batteries may be ordered and the defective batteries 7 are disposed of or returned to the battery supply company.

The term “comprising” (and its grammatical variations) as used herein is used in the inclusive sense of “having” or “including” and not in the exclusive sense of “consisting only of”.

1. A battery recharging and replacement system for use with a battery-powered device, said system comprising:
(i) at least three rechargeable batteries each with a unique identifier;
(ii) a charger for charging said batteries;
(iii) a measurement means for measuring the remaining useful life of each of said batteries; and
(iv) a monitor means for identifying that any one or more of said batteries are at or near the end of their usable life; and
wherein during use and charging of said batteries, said measurement means maintains a record of the remaining useful life of each said batteries, and when a first of said batteries enters a first predetermined range of overall cumulative discharge, said monitor means identifies that battery for imminent replacement, and then determines whether at least a second battery is within a second predetermined range centred on the first battery, if the first battery is within the first predetermined range and at least a second battery is within the second predetermined range, said monitor means identifies both batteries for replacement.

2. A battery recharging and replacement system as claimed in claim 1, wherein remaining useful life is the inverse of cumulative discharge.

3. A battery recharging and replacement system as claimed in claim 2, wherein if the first of said batteries reaches the lower limit of remaining charge capacity prior to the second of said batteries reaches the upper limit of remaining charge capacity, then said monitor means will identify both batteries for replacement if said second battery is in a predetermined tolerance range near the upper limit of remaining charge capacity.

4. A battery recharging and replacement system as claimed in claim 2, wherein said monitor means is connected to a remotely located computer for the ordering and dispatch of batteries, said monitor means providing data to said computer when batteries are identified for replacement.

5. A battery recharging and replacement system as claimed in claim 3, wherein said monitor means is connected to a remotely located computer for the ordering and dispatch of batteries, said monitor means providing data to said computer when batteries are identified for replacement.

6. A battery recharging and replacement system as claimed in claim 1, wherein when said monitor means identifies said batteries for replacement said batteries are prevented from being recharged by said recharger.

7. A battery recharging and replacement system as claimed in claim 2, wherein said measurement means for measuring the cumulative discharge of each of said batteries, is a device interconnected to or integral with said recharger.

8. A battery recharging and replacement system as claimed in claim 2, wherein said measurement means for measuring the cumulative discharge of each of said batteries is a plurality of measurement devices, each of said measurement devices is disposed on and associated with a respective one of said batteries.

9. A battery recharging and replacement system as claimed in claim 2, wherein said measurement means for measuring the cumulative discharge of each of said batteries, is a measurement apparatus interconnected to or integral with said recharger and a plurality of measurement devices, each of said measurement devices disposed on and associated with a respective one of said batteries.

10. A battery recharging and replacement system as claimed in claim 9, wherein said measurement apparatus is adapted to maintain and record a separate record of cumulative discharge for a particular battery to that maintained and recorded by the measurement device associated with that particular battery.

11. A battery recharging and replacement system as claimed in claim 10, wherein said separate record of cumulative discharge maintained by said measurement apparatus may be compared with respect to that maintained and recorded by the measurement device associated with the respective battery.

12. A battery replacement system, wherein said system detects and measures remaining battery life in at least two batteries, and when said system detects that the level of battery performance falls below a first predetermined range relative to overall battery life, said system defines a cluster of batteries and replaces the cluster of batteries, wherein said cluster of batteries is defined by at least first and second batteries being proximal to each other in terms of battery life and within a predetermined second range in respect to each other.
